(19) United States
(12) Patent Application Publication
(10) Pub. No.: US 2003/0039919 A1
(43) Pub. Date: Feb. 27, 2003

(54) Fluorine-containing compounds and polymers derived therefrom

(76) Inventors: David Bradley, Buffalo, NY (US); Dale Hangey, Midlothian, VA (US); Jing J. Ma, West Seneca, NY (US); David Nalewajek, West Seneca, NY (US); Andrew Poss, Kenmore, NY (US); Michael Van Der Puy, Amherst, NY (US); George Samuels, Williamsville, NY (US); George Shia, Amherst, NY (US); Rajiv R. Singh, Getzville, NY (US); Ellen Swan, Lancaster, NY (US); Raymond H. Thomas, Pendelton, NY (US); Gary Zyhowski, Lancaster, NY (US)

Correspondence Address: Synnestvedt & Lechner LLP, 2600 Aramark Tower, 1101 Market Street, Philadelphia, PA, 19107-2950, US

(21) Appl. No.: 10/174,180

(22) Filed: Jun. 18, 2002

Related U.S. Application Data
(60) Provisional application No. 60/299,049, filed on Jun. 18, 2001.

(51) Int. Cl. G03F 7/038

(52) U.S. Cl. 430/270.1; 430/311

(57) ABSTRACT

An optical device comprising a polymer comprising at least one repeating unit derived from a compound of the following formula:

W—Y—O-Z

wherein W is hydrogen, X or X—O—, X is a monovalent unsaturated organic moiety; Y is a divalent organic moiety; and Z a monovalent fluorinated organic moiety.

### CROSS-REFERENCE TO RELATED APPLICATION

This application claims priority to U.S. Provisional Application Ser. No. 60/299,049, which was filed with the United States Patent and Trademark Office on Jun. 18, 2001, and is incorporated herein by reference.

### FIELD OF INVENTION

The present invention relates generally to fluorine-containing compounds, and polymers derived therefrom, for use in compositions used for optical coatings applications. The present invention further relates to methods of making fluorine-containing compounds and polymers derived therefrom, compositions comprising the compounds and/or polymers of the present invention, methods of coating substrates, and the coated products derived therefrom.

### BACKGROUND

There is a need for optically-clear coatings and waveguides, especially at very high frequencies. For example, in the field of photolithographic chip manufacturing, the use of light having wavelengths in the order of 157 nm is not uncommon. Unfortunately, conventional photoresists tend to absorb light at these frequencies. Once the photoresist begins to absorb light, its ability to define sharp lines of contrast on the chip is degradaed, thereby resulting in a loss of resolution. This loss in resolution limits the density of the circuitry which can be imprinted on the chip, and, therefore, limits the miniaturization of the chip. Accordingly, there is a need for coatings and waveguides which remain optically clear even at relatively high light frequencies. The present invention fulfills this need among others.

### SUMMARY OF THE INVENTION

The present invention is directed to a family of fluorine-containing compounds, and polymers derived therefrom, for use in the preparation of compositions used in various optical coatings applications. The compounds of the present invention are advantageous over fluorinated compounds used conventionally to prepare optical coatings in that the present compositions tend to biodegrade more readily, and, upon biodegradation, tend to form compounds that are more environmentally-desirable and less toxic than conventional compounds. In addition, the compounds and polymers of the present invention exhibit relatively high chemical and thermal resistance, relatively high electrical resistivity, relatively low surface energy, and relatively low refractive index, making them particularly suitable for use in coating optical substrates.

Accordingly, one aspect of the present invention relates to fluorine-containing compounds. In preferred embodiments, the present invention provides fluorine-containing compounds which are described by the following formula:

W—Y—O-Z (1)

wherein: W is hydrogen, X, or X—O—, X is a monovalent unsaturated organic moiety; Y is a divalent organic moiety; and Z a monovalent fluorinated organic moiety.

Another aspect of the present invention is a family of polymers comprising at least one repeating unit derived from the compounds of the invention. In preferred embodiments, the polymers of the present invention comprise at least repeating unit derived from a compound of formula (1).

The compounds and polymers of the present invention are useful in compositions for coating optical substrates. Therefore, yet another aspect of the present invention is a composition comprising a polymer of the present invention.

Yet another aspect of the present invention relates to a method for treating an optical substrate with a composition of the present invention comprising applying a layer of the composition of the invention onto a substrate and curing the composition on the substrate.

The inventive method produces articles of manufacture having optical coatings. Therefore, still another aspect of the present invention is a substrate having a water-resistant and/or soil-resistant coating produced via the method of the present invention.

The compositions comprising polymers or compounds of the present invention may be cured to form films. Therefore, another appeal of the present invention also includes the films produced by curing the compositions of the present invention.

### DESCRIPTION OF THE PREFERRED EMBODIMENTS

Monomer Compounds

In certain embodiments, the present invention provides fluorine-containing amide compounds which are described by the formula as follows:

W—Y—O-Z (1)

wherein: W is hydrogen, X, or X—O—, X is a monovalent unsaturated organic moiety; Y is a divalent organic moiety; and Z a monovalent fluorinated organic moiety.

X can be any suitable monovalent moiety comprising at least one double bond, triple bond, or cyclic portion. Examples of suitable unsaturated organic moieties include substituted or unsubstituted alkenyls, substituted or unsubstituted alkynyls, substituted or unsubstituted aralkyls, substituted or unsubstituted heterocyclic groups, substituted or unsubstituted vinyl ethers, substituted or unsubstituted carbonyl-containing groups, such as those derived from ketene acetals, urethanes, acrylates, and the like.

X as a substituted or unsubstituted alkenyl can be any substituted or unsubstituted, straight-chain or branched alkenyl group having from about 2 to about 20 carbons atoms. Examples of suitable fluorinated C₂-C₂₀ alkenyl groups include, for example, vinyl, allyl, n-propenyl, isopropenyl, n-butenyl, isobutenyl, sec-butenyl, n-pentenyl, isopentenyl, neopentenyl, tert-pentenyl, hexenyl, heptenyl, octenyl, nonenyl, decenyl, undecenyl, dodecenyl groups, and the like, as well as, dienes, such as, allene, penta-2,4-diene, and the like. Any of these groups may be further substituted with, for example, halogen, hydroxyl, alkyl, fluoroalkyl, alkoxy, aryloxy, arylalkyl groups, and the like. In a preferred class of alkenyls, X is a substituted or unsubstituted C₂-C₆ alkenyl including for example, vinyl, perhalogenated alkenys, such as,CF₃CF═CF—, CF₂═CF—, CFCl═CF—, as well as, halo-substituted allyls, such as those derived from, 2-methyl-3-butenyl halide, butenyl halides, 3-methyl-2-butenyl halide, 3-butenyl halide, 3-methyl-3-butenyl halide, 2-butenyl halide, 2-methyl-2-butenyl halide, 1,4-dihalo-2-butene, 1,2-dihalo-2-propane, 2-methyl 1,4-dihalo-2 butene, 1,1,2 trifluoro-3-halo-1-propene.

X as a substituted or unsubstituted alkynyl can be any substituted or unsubstituted, straight-chain or branched alkynyl group having from about 2 to about 20 carbons atoms. Examples of suitable C₂-C₂₀ alkynyl groups include substituted or unsubstituted propargyl groups, as well as, alkynyls derived from 1-halo-2-butyne, 1,4- dihalo-2-butyne, 1-halo-3-butyne, and the like. Any of these groups may be further substituted with, for example, halogen, hydroxyl, alkyl, fluoroalkyl, alkoxy, aryloxy, arylalkyl groups, and the like. In a preferred class of alkynyls, X is a substituted or unsubstituted C₂-C₆ alkynyl.

X as a substituted or unsubstituted aralkyl can be any substituted or unsubstituted aralkyl group having from about 6 to about 20 carbons atoms. Examples of suitable C₆-C₂₀ aralkyl groups include vinyl benzyl and divinyl benzyl groups. Any of these groups may be further substituted with, for example, halogen, hydroxyl, alkyl, fluoroalkyl, alkoxy, aryloxy, arylalkyl groups, and the like. In a preferred class of aralkyls, X is a substituted or unsubstituted C₉-C₁₂ aralkyl such as vinyl benzyl, halo-subsituted vinyl benzyl, divinyl benzyl, and halo-substituted divinyl benzyl.

X as a substituted or unsubstituted heterocyclic group can be any substituted or unsubstituted cyclic compound having at least one heteroatom (N, O, or S) in the ring structure. Suitable heterocyclic groups include those having from about 2 to about 12 carbon atoms, including substituted or unsubstituted epoxy groups, oxetane groups, including halo-substituted oxetane groups, such as those derived from 3-bromemethyl-3-methyl oxetane, 3-bromomethyl oxetane, and the like, as well as, groups derived from furfuryl alcohols, such as bis-hydroxy-methyl furan.

X as a substituted or unsubstituted vinyl ether group can be derived from any substituted or unsubstituted vinyl ether, alkyl vinyl ether, cyclic vinyl ether, linear or branched di-vinyl ether, or linear or branced tri-vinyl ether. Examples of suitable vinyl ether groups include those derived from ethylvinylether, trimethylolpropane vinyl ether, butylvinyl ether, trimethylol propane divinyl ether, cyclohexylmethyl vinyl ether, pentaerytherital vinylether, glycerolmono vinyl ether, pentaerytherital divinyl ether, glycerol divinyl ether, pentaerytheriotal trivinyl ether, and the like. Any of these groups may be further substituted with, for example, halogen, hydroxyl, alkyl, fluoroalkyl, alkoxy, aryloxy, arylalkyl groups, and the like.

In the compounds of the present invention, Y is a divalent organic moiety comprising a carbon atom available for bonding to a W group and a carbon atom available for bonding to an —O-Z group, wherein the carbon atom(s) available for bonding to the W and —O-Z groups may be the same carbon atom or different carbon atoms. Y as a divalent organic moiety may be any suitable divalent substituted or unsubstituted aliphatic or aromatic moiety.

Suitable divalent substituted or unsubstituted aliphatic or aromatic moieties include those derived from monovalent aliphatic or aromatic groups. As will be recognized by those of skill in the art, divalent radicals can be derived from a wide variety of monovalent aliphatic or aromatic groups by removing one hydrogen from a carbon atom of the monovalent group. For example, suitable divalent aliphatic moieties for use in the present invention include those derived from alkyls, alkenyls, alkynyls, cycloalkyls, cycloalkenyls, cycloalkynyls, heteroalkyls, heteroalkenyls, heteroalkynyls, aryls, aralkyls, and combinations of two or more thereof.

Y as an divalent aliphatic moiety can be derived, as indicated above, from any of a wide range of alkyl groups. Preferably, Y is derived from an alkyl group having from about 1 to about 20 carbon atoms. The C₁-C₂₀ alkyl group may be a straight chain or branched molecule, for example: methyl, ethyl, n-propyl, isopropyl, n-butyl, isobutyl, tert-butyl, n-pentyl, neopentyl, n-hexyl, n-heptyl, -octyl, 2-ethylhexyl, nonyl, decyl, and the like. Additionally, any of the alkyl groups, from which Y is derived, may be further substituted with other substituents including alkoxy and aryloxy groups, such as —O-Z groups wherein each Z in the compound of Formula 1 is independently selected, as well as, halogen, alkyl, fluoroalkyl, arylalkyl groups, and the like. (As used herein, the term “independently selected” means that each Z group in a given compound of Formula 1 can be the same or different from any one or more Z groups present in the compound.) In a preferred class of divalent moieties, Y is derived from a substituted or unsubstituted C₂-C₆ alkyl, and more preferably a substituted or unsubstituted C₂-C₄ alkyl. Examples of such more preferred Y moieties include: —CH₂CH₂—, —CH(CH₃)CH₂—, —C(CH₂OZ)₂—CH₂—, —C(CH₃)₂CH₂—, and the like.

Y as an divalent aliphatic moiety can be derived from any of a wide range of alkenyl groups. Preferably, Y is derived from an alkenyl group having from about 2 to about 20 carbon atoms. The C₂-C₂₀ alkenyl may be a straight chain or branched molecule, for example, ethenyl, propenyl, butenyl, penentyl, hexenyl, heptenyl, octenyl, 2-ethylhexenyl, nonenyl, decenyl, and the like. Additionally, any of the alkenyl groups, from which Y is derived, may be further substituted with other substituents including alkoxy and aryloxy groups, such as —O-Z groups wherein each Z in the compound of formula 1 is independently selected, as well as, halogen, alkyl, fluoroalkyl, arylalkyl groups, and the like.

Y as an divalent aliphatic moiety can be derived from any of a wide range of alkynyl groups. Preferably, Y is derived from an alkynyl group having from about 2 to about 20 carbon atoms. The C₂-C₂₀ alkynyl may be a straight chain or branched molecule, for example, ethynyl, propynyl, butynyl, penyntyl, hexynyl, heptynyl, octynyl, 2-ethylhexynyl, nonynyl, decynyl, and the like. Additionally, any of the alkynyl groups, from which Y is derived, may be further substituted with other substituents including alkoxy and aryloxy groups, such as —O-Z groups wherein each Z in the compound of Formula 1 is independently selected, as well as, halogen, alkyl, fluoroalkyl, arylalkyl groups, and the like.

Y as an divalent aliphatic moiety derived from a cycloalkyl group is preferably derived from a cycloalkyl having from about 3 to about 20 carbon atoms. Examples of suitable C₃-C₂₀ cycloalkyls include, for example, cyclopentyl, cyclohexyl, cycloheptyl, cyclooctyl, cyclononyl, cyclodecyl, and the like. Additionally, any of the cycloalkyl groups, from which Y is derived, may be further substituted with other substituents including alkoxy and aryloxy groups, such as —O-Z groups wherein each Z in the compound of Formula 1 is independently selected, as well as, halogen, alkyl, fluoroalkyl, arylalkyl groups, and the like.

Y as an divalent aliphatic moiety derived from a cycloalkenyl group is preferably derived from a cycloalkenyl having from about 5 to about 20 carbon atoms. Examples of suitable C₅-C₂₀ cycloalkenyls include, for example, cyclopentenyl, cyclohexenyl, cycloheptenyl, cyclooctenyl, cyclononenyl, cyclodecenyl, and the like. Additionally, any of the cycloalkenyl groups, from which Y is derived, may be further substituted with other substituents including alkoxy and aryloxy groups, such as —O-Z groups wherein each Z in the compound of Formula 1 is independently selected, as well as, halogen, alkyl, fluoroalkyl, arylalkyl groups, and the like.

Y as an divalent aliphatic moiety derived from a cycloalkynyl group is preferably derived from a cycloalkynyl having from about 5 to about 20 carbon atoms. Examples of suitable C₅-C₂₀ cycloalkynyls include, for example, cyclopentynyl, cyclohexynyl, cycloheptynyl, cyclooctynyl, cyclononynyl, cyclodecynyl, and the like. Additionally, any of the cycloalkynyl groups, from which Y is derived, may be further substituted with other substituents including alkoxy and aryloxy groups, such as —O-Z groups wherein each Z in the compound of Formula 1 is independently selected, as well as, halogen, alkyl, fluoroalkyl, arylalkyl groups, and the like.

Y as derived from a heteroalkyl, heteroalkenyl, or heteroalkynyl preferably comprises a divalent moiety derived from an open-chain or cyclic, alkyl, alkenyl, or alkynyl group, as described above, further including at least one heteroatom, such as, nitrogen (N) and/or sulfur(S).

Y as a divalent aromatic moiety derived from an aryl group is preferably derived from an aryl comprising from about 5 to about 20 carbon atoms. The C₅-C₂₀ aryl may be, for example, phenyl, o-tolyl, m-tolyl, p-tolyl, o-xylyl, m-xylyl, p-xylyl, alpha-naphthyl, beta naphthyl and the like. Additionally, any of the aryl groups, from which Y is derived, may be further substituted with other substituents including alkoxy and aryloxy groups, such as —O-Z groups wherein each Z in the compound of Formula 1 is independently selected, as well as, halogen, alkyl, fluoroalkyl, arylalkyl groups, and the like. In a preferred class of divalent moieties, Y is derived from a substituted or unsubstituted C₆-C₈ aryl, including compounds of the following formula: —C₆H₄₋ₚ(O-Z)ₚ-, wherein p is from about 0 to about 4. More preferably, Y is an oxy-substituted C₆ aryl such as —C₆H₄— or —C₆H₃(OZ)-.

Y as derived from an aralkyl is preferably derived from an aralkyl having from about 6 to about 20 carbon atoms. The C₆-C₂₀ aralkyl may be, for example, benzyl, 4-methylbenzyl, o-methylbenzyl, p-methylbenzyl, diphenylmethyl, 2-phenylethyl, 2-phenylpropyl, 3-phenylpropyl and the like. Additionally, any of the aralkyl groups, from which Y is derived, may be further substituted with other substituents including alkoxy and aryloxy groups, such as —O-Z groups wherein each Z in the compound of Formula 1 is independently selected, as well as, halogen, alkyl, fluoroalkyl, arylalkyl groups, and the like.

By way of further illustration, the following is a list of compounds from which can be derived further examples of divalent aliphatic and aromatic Y groups suitable for use in the present invention. In general, it is to be understood that suitable Y groups may be derived from the compounds listed below, for example, by removing a hydrogen or hydroxyl group from a carbon atom (to form a carbon atom for bonding to an amide nitrogen), and removing a hydrogen or hydroxyl group from a carbon atom (which can be the same or different carbon atom for bonding to the nitrogen) to form a carbon atom for bonding to an —O-Z group. The compounds include:

aliphatic alcohols, such as, 1,3-propanediol, 1,2-propanediol, -butanol, sec-butanol, isobutanol, tert-butanol, dihydroxy butanes,1,4-butanediol, 1,3-butanediol, 1,2-butanediol, 2-methyl-1-3-propanediol, neopentylglycol, 2-pentene 1,5-diol, 2-pentene 1,4-diol, 2-pentene 4,5-diol, 1-pentene-3,4-diol, 1-pentene-4,5-diol, 1-pentene-3,5-diol, 2-butene 1,4-diol, 1-butene-3,4,-diol, 2-butyne 1,4-diol, 1-butyne-3,4-diol, pentane 1,5-diol, pentane 1,4-diol, pentane 1,3-diol, pentane 1,2-diol, pentane 2,5-diol, pentane 2,4-diol, pentane 2,3-diol, 2-methyl-1,1,2,3-propanedtriol, pentane-1,2,3-triol, pentane-1,2,4-triol, pentane-1,2,5-triol, pentane-1,3,5-triol, pentane-1,3,4-triol, pentane-2,3,4-triol, 2-ethyl 1,2,3,-propanetriol, butane 1,2,3,4 tetraol, pentaerytheixtol, pentane 1,2,3,4 tetraol, pentane 1,2,3,5 tetraol, pentane 1,2,4,5 tetraol, 2-methylene-propane-1,3-diol, 2-ethylidne-propane-1,2-diol, 1-isopropyidene-propane-1,3-diol, 2,3-dimethyl-but-2-ene-1,4-diol, 2-ethyl-but-2-ene-1,4-diol, and 2-methyl-but-2-ene- 1,4-diol, 2-Hydroxymethyl-2-methyl-propane- 1,3-diol,. 2-Hydroxymethyl-propane-1,3-diol, 2-Ethyl-2-hydroxymethyl-propane-1,3-diol, 2-Hydroxymethyl-propane-1,2,3-triol, 2-Hydroxymethyl-butane-1,2,3-triol, 2-Hydroxymethyl-butane-1,2,4-triol, 3-Hydroxymethyl-butane-1,2,4-triol, 1,2,3 trihydroxy propane, pentaerythritol, di-pentaerytheritol, tripentaerythritol, glycerol propoxylate, meso-erythritol, HOCH₂[CH(OH)]₂CH₂OH, threitol DL, 1,2,3,4 butanetetrol, sorbitol, HOCH₂[CH(OH)]₄CH₂OH, mannitol, HOCH₂[CH(OH)]₄CH₂OH, dulcitol, iditol, L-sorbose, HOCH₂(HCOH)₃C(O)CH₂OH, 1, 1, 1 tris(hydroxymethyl)ethane, 1, 2, 3 trihydroxy hexane, 1, 2, 6 trihydroxy hexane, trimethylol propane CH₃CH₂(CH₂OH)₃, trimethylol propane ethoxylate CH₃CH₂(CH₂O(CH₂CH₂O)ₓCH₂CH₂OH)₃, trimethylol propane propoxylate CH₃CH₂(CH₂O(CH₃CHCH₂O)ₓCH₃CHCH₂OH)₃, trimethylol propane allyl ether, 1, 4 dihydroxy-2-butene HOCH₂CH═CHCH₂OH, 1, 4 dihydroxy-2-butyne HOCH₂CCCH₂OH, 3-methyl-3-oxetanemethanol CH₃C(CH₂OH)CH₂OCH₂, 3-ethyl-3-oxetanemethanol CH₃CH₂C(CH₂OH)CH₂OCH₂, N, N, bis(hydroxyethyl)acryl-amide, N, N, bis(2-hydroxypropyll)acrylamide, cyclic polyols, such as,1,2-cyclopentonediol, 1,2-cyclohexanedimethanol, 1,3-cyclopentanediol, 1,4-cyclohexandimethanol, 1,2-cyclopentanediol, 1,3-cyclohexandimethanol, 1,2-cyclohexanediol, 1-4-cyclohexandeiol, 1,3,5-cyclohexanetriol, triethanol amine, tetrahydroxyethyl ethylene diamine, 3-amino-1,2-propanediol, 2-amino-2-methyl-1,3-propanediol (HOCH₂)₂CCH₃NH₂, tris(hydroxymethyl)aminomethane (HOCH₂)₃CNH₂, tris(hydroxymethyl)aminomethylacrylamide (HOCH₂)₃CNHC(O)CH═CH₂, methyolacrylamide (HOCH₂NHC(O)CH═CH₂), dihydroxyethylacrylamide (HOCH₂CH₂)₂NC(O)CH═CH₂), dihydroxymethylacrylamide ((HOCH₂)₂NC(O)CH═CH₂), and the methyl substituted acrylamides;

aryl alcohols, such as, benzene 1,2 diol; benzene 1,2,3,4 tetraol; benzene 1,3 diol; benzene 1,2,3,5 tetraol; benzene 1,4 diol; benzene 1,2,4,5 tetraol; benzene 1,2,4 triol; bis phenol A; benzene 1,3,4-triol; bis phenol AF; benzene 1,2,3 - triol; 4, hexafluoroacetone(6FK) phenol; 1,3 bis 6FK benzene; 1,4 bis 6FK benzene; 2-hydroxybenzylalcohol; 3-hydroxybenzylalcohol; 4-hydroxybenzylalcohol; phenylene 1,3-diamine; 1,2-benzene dimethanol; phenylene 1,3-diamine; 1,3-benzene dimethanol; phenylene 1,4-diamine; 1,4-benzene dimethanol; 1,2,3-benzenetrimethanol; 1,2,4,5-benzenetetramethane; 1,2,4-benzenetrimethanol; 1,2,3,4-benzenetetramethane; 1,3,5-benzenetrimethanol; 1,2,3,4-benzenetetramethane, aniline, phenol sulfonic acid;

polymers and copolymers with alcohol functional groups, for example, multiple co-polymers can be prepared with monomers that contain “free” hydroxyl groups such as hydroxethyl(meth)acrylate, hydroxpropyll(meth)acrylate, allyl alcohol, and hydroxy vinyl ethers such as hydroxyethyl vinyl ether and hydroxybutyl vinyl ether, for example, poly(2-hydroxyethylacrylate), poly(2-hydroxyethylmethacrylate), poly(2-hydroxypropylacrylate), poly(4-hydroxystyrene), poly(hydroxyethyl vinyl ether), poly(hydroxybutyl vinyl ether), poly(styrene-co-allyl alcohol), polyvinyl alcohols, poly(vinyl alcohol-co-ethylene), poly(vinylchloride-co-vinylacetate-co-2-hydroxypropyl acrylate), poly(vinyl phenol-co-methyl methacrylate), poly(vinyl phenol-co-2-hydroxyethyl methacrylate), poly(vinyl pyridine-co-2-hydroxymethylacrylate);

saccharides, which as used herein means a saccharide residue wherein a hydrogen atom is removed from the hydroxyl group attached to the anomeric carbon atom of the saccharide and is replaced with a polymerizable moiety; the remaining hydroxyl groups are partially or completely replaced by fluoroethers; more specifically they are the saccharide residues of monosaccharide or oligosaccharide having about 1 to about 10, preferably about 1 to about 5, more preferably about 1 to 3, sugar units; and their respective glycans, for example, methylglueth-10, or other ethylene oxide or propylene oxide adducts of the saccharide;

water soluble gums, including Guar, Gum Arabic, Karaya, Tragacanthin, Xanthan;

vinyl ethers including, ethylvinylether, trimethylolpropane vinyl ether, butylvinyl ether, trimethylol propane divinyl ether, cyclohexylmethyl vinyl ether, pentaerytherital vinylether, glycerolmono vinyl ether, pentaerytherital divinyl ether, glycerol divinyl ether, pentaerytheriotal trivinyl ether, dioxole;

furfuryl alcohol, bis-hydroxy-methyl furan, linear or branched ketene acetals of the formula CₙH₂ₙO₂, wherein n is and integer of from about 4 to about 10;

electron deficient vinyl ethers of the formula CₙF₂ₙ₊₁XClₓO and R_{f}C₂F₂O, wherein n is an integer from 0 to 8 and R_{f} is a CₙF₂ₙ₊₁ or halogen radical including Cl, F, Br, I; such as, CF₃CF═CFO, CF₂═CFO, CFCl-CFO;

linear or branched heteroallyls of the formula CₙH₂ₙ₋₁X, and linear or branched di-halo heteroallyls of the formula CₙH₂ₙX₂, wherein n is an integer from 3 to 8 and X is a halogen radical, Cl, F, Br, I; as well as

functionalized allyl alcohols, propargyl alcohols, hydroxyvinyl ether, hydroxybutyl ether, hydroxyethylacrylate, hydroxyethylmethacrylate, 2-hydroxypropylacrylate, 2-hydroxypropylmethacrylate, 4-hydroxybutylacrylate, 4-hydroxybutylmethacrylate, HOCH₂CH₂O(—CH₂CH₂O—)ₓCOR═CH₂, HOCH(CH₃)CH₂O(—CH(CH₃)CH₂O—)ₓCOR═CH₂, HOCH₂CH₂CH₂CH₂O(—CH₂CH₂CH₂CH₂O—)ₓCOR═CH₂, glycerin acrylate, glycerin methacrylate, glycerin diacrylate, glycerin dimethacrylate, pentaerythritol acrylate, pentaerythritol diacrylate, pentaerythritol triacrylate, pentaerythritol methacrylate, pentaerythritol dimethacrylate, pentaerythritol trimethacrylate, methyl 2 -hydroxymethyl methyl acrylate, CH₃OC(O)(HOCH₂)C═CH₂, CF₃CHFCF₂CH₂OH, and HCF₂CF₂CH₂OH, as well as,

any of the compounds listed hereinabove wherein one or more of the hydroxyl groups is replaced with an —O-Z group.

Z can be any suitable fluorinated organic moiety. Suitable fluorinated organic moieties include, fluorinated alkyl groups, fluorinated alkenyl groups, fluorinated aryl groups, fluorinated ether groups, and the like. In general, when two or more Z groups are present in a compound of Formula 1, including those optionally substituted on Y moieties, such Z groups are independently selected from one another in the molecule.

Z as a fluorinated alkyl group may comprise any substituted or unsubstituted, straight-chain or branched alkyl group having from about 1 to about 20 carbons atoms and at least one fluorine substituent. Suitable fluorinated alkyl groups include perfluorinated and partially-fluorinated alkyls, such as, for example, perfluorinated and partially-fluorinated methyl, ethyl, n-propyl, isopropyl, n-butyl, isobutyl, sec-butyl, tert-butyl, n-pentyl, isopentyl, neopentyl, tert-pentyl, hexyl, heptyl, octyl, nonyl, decyl, undecyl, dodecyl groups, as well as other fluorinated alkyls described by the formulae F(CF₂)ₙ—, F(CH₂)ₐ(CH₂)ₐ—, Cl(CF₂CFCl)ₐ—, HO(CH₂)_{b}(CF₂)ₐ—Cl (CF₂CFCl)ₙ(CH₂)ₘ-, H(CF₂)_{b}(CH₂)ₐ-, wherein a is an integer of from about 1 to about 16 and b is an integer from about 1 to about 8, and the like. Any of these groups may be further substituted with, for example, chlorine, hydroxyl, alkyl, fluoroalkyl, alkoxy, aryloxy, arylalkyl groups, and the like. In a preferred class of fluorinated alkyls, when X is an R²-substituted nitrogen, Z is a substituted or unsubstituted C₁-C₇ fluorinated alkyl including, for example, isomers of tetrafluoroethyl, such as, —CHF—CF₃ or —CF₂CHF₂, isomers of chlorotrifluoroethyl, such as, —C(Cl)F—CHF₂ or —CF₂—CH(Cl)F, isomers of hexafluoropropyl, such as, —CF₂CHFCF₃, —CHFCF₂CF₃, or —CF₂CF₂CHF₂, or fluorinated C₆ alkyls such as —CF(CF₂CF₃)—CH(CF₃)₂, —CF(CF₃)—CH₂—CF(CF₃)₂ and —CF(CF₃)—CHF—CF(CF₃)₂. In certain particularly preferred embodiments, Z is —CF₂CHFCF₃, —CF(CF₂CF₃)—CH(CF₃)₂, —CF(CF₃)—CH₂—CF(CF₃)₂ or —CF(CF₃)—CHF—CF(CF₃)₂. In certain preferred embodiments when X is oxygen, Z is a C₁-C₇ fluorinated alkyl comprising only C, H, and F atoms, but having no —CH₂— groups. Examples of particularly preferred Z groups include —CF₂CHFCF₃, —CF(CF₂CF₃)—CH(CF₃)₂, —CF(CF₃)—CH₂—CF(CF₃)₂ and —CF(CF₃)—CHF—CF(CF₃)₂.

Z as a fluorinated alkenyl group may comprise any substituted or unsubstituted, straight-chain or branched alkenyl group having from about 2 to about 20 carbons atoms and at least one fluorine substituent. Examples of suitable fluorinated C₂-C₂₀ alkenyl groups include perfluorinated and partially-fluorinated alkenyls, such as, for example, perfluorinated and partially-fluorinated ethenyl, -propenyl, isopropenyl, n-butenyl, isobutenyl, sec-butenyl, n-pentenyl, isopentenyl, neopentenyl, tert-pentenyl, hexenyl, heptenyl, octenyl, nonenyl, decenyl, undecenyl, dodecenyl groups, and the like. Any of these groups may be further substituted with, for example, halogen, hydroxyl, alkyl, fluoroalkyl, alkoxy, aryloxy, arylalkyl groups, and the like. In a preferred class of fluorinated alkenyls, when X is an R²-substituted nitrogen, Z is a substituted or unsubstituted C₂-C₁₈ alkenyl including for example, isomers of chlorodifluoroethenyl, such as, —C(Cl)═CF₂ and —C(F)═C(Cl)F, trifluoroethenyl, isomers of pentafluoropropenyl, such as, —CF═CF—CF₃ and —CF₂—CF═CF₂, fluorinated alkenyls derived from hexafluoropropene, such as, for example,—CF═CF—CF₃, and dimers and trimers of hexafluoropropene. In certain particularly preferred embodiments, Z is a C₂-C₆ alkenyl, such as, —CF═CF—CF₃ or —C(C₂F₅)═C(CF₃)₂. In certain preferred embodiments when X is oxygen, Z is a C₂-C₆ alkenyl comprising C, H, and F, but having no CH₂ groups.

Z as a fluorinated aryl group may comprise any substituted or unsubstituted aryl group having from about 2 to about 20 carbons atoms and at least one fluorine substituent. Examples of fluorinated aryl groups include fluorinated: phenyl, tolyl, xylyl groups, and the like. Any of these groups may be further substituted with, for example, halogen, hydroxyl, alkyl, fluoroalkyl, alkoxy, aryloxy, arylalkyl groups, and the like. In a preferred class of fluorinated aryl, Z is a fluorinated aryl having about six carbon atoms or less.

In certain embodiments Z is a substituted or unsubstitued ether group. Z as a substituted or unsubstitued ether group may comprise any straight-chain or branched ether group. Examples of suitable ether groups include those described by the formulae (CF₃)₂CFO(CF₂)ₐ-, (CF₃)₂CFO(CF₂)ₐ-, CF₃O(CF₂O))_{c}—(CF₂CF₂))_{c}—(CF(CF₃)—CF₂O)C(CH₂)_{b}-, wherein c is from about 1 to about 20, and a and b are as previously defined.

Other suitable Z groups include alkyl, alkenyl, or aryl groups derived from F-telomers, hexafluoroacetone (6 FK), pentafluoropropene, perfluoroaromatic compounds, polyfluorovinyl ethers (PFVE), fluorochloro olefins, perfluoroisobutylene (PFIB), hexafluoroisobutylene (HFIB), and derivatives thereof, and perfluoromethyl vinyl ether, perfluoropropyl vinyl ether, and pentafluoropropenes such as CF₃CH═CF₂ and CF₃CF═CFH, derived from 1,1,1,3,3 pentafluoropropane.

As noted above, in certain embodiments, W is hydrogen. Examples of certain preferred compounds in embodiments of the present invention wherein W is hydrogen include, CF₃CFHCF₂OCH═CH₂, CF₃CFHCF₂O—(CH₂)ₙ—OCH═CH₂,, CF₃CF═CFO═(CH₂)ₙ—O— CH═CH₂ and the associated diols, CF₃CFHCF₂—O—(CH₂)ₙ—CH (CF₃CFHCF₂O—(CH₂)ₙ)-(CH₂)ₙ—O—CH═CH₂, where n is an integer from 1 to 20, triols, such as would be formed by coupling hexafluoropropene with 2 suitable olefins or 2 hexafluoropropyl (HFP) radicals with one suitable olefin, tetraols, such as would be formed by coupling 1 HFP radical with 3 suitable olefins, or 2 HFP radicals coupled with 2 suitable olefins, or 3 HFP radicals coupled with 1 suitable olefin, or 4 HFP radicals combined of the formula (CF₃CF═CFOCH₂)₄C or (CF₃CFHCF₂OCH₂)₄C. Examples of particularly preferred compounds of Formula 1 wherein W is hydrogen, include, CF₃CFHCF₂OCH₂CH₂OCH═CH₂ (molecular weight 238.14, with a H/100 amu ratio of 3.36), CF₃CF═CFOCH₂CH₂OCH═CH₂ (molecular weight 218.13, with a H/100 amu ratio of 3.21), CF₃CF═CFOCH₂CH₂OCF═CFCF₃ (molecular weight 322.12, with a H/100 amu ratio of 1.24), and C₂H₅C[CH₂OCF═CFCF₃]₃ (molecular weight 524.25, with a H/100 amu ratio of 2.09).

Method of Making Compositions

Although applicants do not wish to be bound by or to any particular theory of operation, Reaction Scheme I illustrates one possible mechanism for the formation of certain compounds of the present invention by reacting a compound of formula A with a fluoroolefin (Z-V, wherein V is H or F).

Reaction Scheme I

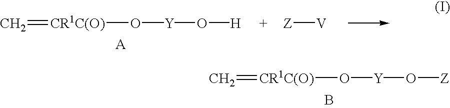

It should be appreciated that any —OH groups present on the R² or Y groups of compound A can also be converted to —O-Z groups in the reaction shown in Scheme I.

Any of a wide range of compounds A can be used in the preparation of the compounds of the present invention. Examples of such compounds include 2-hydroxyethyl methacrylate, 4-hydroxybutyl acrylate, 2-hydroxyethyl acrylate and the like. A variety of such compounds are available commercially or are obtainable by art-recognized procedures. For example, compounds having the structure of Compound A can be made conventionally via the reaction:

H—O—Y—O—H+CH₂═CR¹C(O)Cl→CH₂═CR¹C(O)—O—Y—O—H.

Those skilled in the art will appreciate that the amounts of Compound A and fluoroolefin compounds to be used according to the present invention will depend on many variables, including the particular reagents being used and the desired yield from the reaction. The amount of reagents used is preferably an amount effective to achieve about 30% or better, more preferably about 50% or better, even more preferably about 80% or better, and even more preferably about 90% or better, of conversion of the compound A starting material to desired Compound B product. Generally, the ratio of —OH moieties of compound A to be converted to —O-Z groups to fluoroolefin may vary from about 2:1 to about 1:2. Preferably, the ratio of —OH moieties to fluoroolefins is from about 1.5:1 to about 1:1.5, and even more preferably from about 1:1.05 to about 1:1.4.

The fluoroolefin used may be in either a liquid or gas state. For liquid fluoroolefins, such as perfluoro-2-methyl-2-pentene, the fluoroolefin is added using any of a wide range of known methods to the reaction mixture. For gaseous fluoroolefins, the fluoroolefin reagent may be bubbled subsurface into the reaction mixture.

In certain embodiments, the reaction of Scheme I takes place in the presence of a base. Any of a wide range of bases can be used in the reaction according to the present invention. Examples of suitable bases include organic bases, such as, ammonia, secondary amines, tertiary amines including triethylamine, dimethylaniline, pyridine and the like, as well as, inorganic bases, such as, earth metal hydroxides, including sodium hydroxide and potassium hydroxide, and earth metal carbonates, such as, potassium carbonate and sodium carbonate, and the like. Certain preferred bases include those having a pKa value of about 9 to about 11. Examples of preferred bases include triethylamine, potassium carbonate and sodium carbonate.

Any suitable amount of base may be used in the reaction of the present invention. The amount of base used should be at least sufficient to provide a catalytic amount. Larger amounts of base may be used to partially or completely bind the hydrogen fluoride and/or hydrogen chloride by-products formed by the reaction. Excesses of base, for example, up to about 5 equivalents, may be used. The product distribution may be altered as a factor of the amount of based used. In light of the disclosure herein, those of skill in the art will be readily able to determine the amount of base for use in a given application, without undue experimentation.

In certain preferred embodiments, the present reaction is conducted in a solvent. Suitable solvents include substantially anhydrous, aprotic solvents, such as, methylene chloride, chloroform, carbon tetrachloride, dichloroethane, trichloroethane, tetra-chloroethane, benzene, toluene, chlorobenzene, dimethylformamide, tetramethylene sulphone, dimethyl sulfoxide, acetonitrile, glyme, diglyme, tetrahydrofuran, and the like. Preferred solvents include dimethylformamide and acetonitrile.

Those skilled in the art will appreciate that the conditions under which the reaction occurs, including the temperature, pressure and period of reaction, will depend on numerous factors, including the particular starting reagents used and the desired reaction yield. In view of the teachings contained herein, those skilled in the art will be able to select the appropriate reaction conditions to achieve the particular desired result. In certain preferred embodiments, the reaction is conducted at a temperature in the range of from about −20 to about 50° C., more preferably in the range of about −10 to about 25° C., and even more preferably about −5 to about 10° C.

The compounds of the structure B obtained from the aforementioned reaction may be purified by conventional methods known to those skilled in the art. For example, aqueous washes, drying, concentrating under reduced pressure, distillation, HPLC separation, and the like may be used.

Alternatively, compounds of the present invention may be obtained by reacting a diol of the formula HO—Y—OH with a fluoroolefin of the formula Z—V to form an alcohol of the formula HO—Y—O-Z, and subsequently subjecting the alcohol to esterification reaction conditions to form a compound of the present invention. Examples of reaction conditions and starting materials suitable for such a reaction scheme are described Japanese Patent No. 62103034 A2 (issued to NEOS Co. Ltd.), which is incorporated herein by reference.

Polymers and Polymerization

The present invention further provides polymers comprising a repeating unit derived from a compound of the present invention, or a mixture of two or more compounds of the present invention.

In certain embodiments, the polymers of the present invention comprise homopolymers, comprising repeating units all derived from the same compound of the present invention. In certain other embodiments, the repeating units of the present polymer are derived from a plurality of compounds of the instant invention. Such compositions may be copolymers, block copolymers, terpolymers, polymers comprising four or more different classes of repeating units, combinations of two or more thereof, and the like.

In yet other embodiments, the polymer of the present invention may include one or more repeating units derived from other monomers, oligomers, or polymer compounds that have been copolymerized with at least one compound of the present invention. Suitable other monomers, oligomers, and polymer compounds include, for example, hydrophobic monomers, including, esters of acrylic or methacrylic acid, and longer chain alkyl, dialkyl and aryl acrylamides, where the alkyl or aryl groups include the following: methyl, ethyl, propyl, isopropyl, butyl, isobutyl, amyl, hexyl, phenol and substituted phenols, e.g. 2,6 dimethyl-phenol, benzyl and substituted benzyl materials, octyl, iso-octyl, ethyl hexyl, nonyl, decyl, undecyl, dodecyl, lauryl, stearyl, cyclopentyl, cyclohexyl, and other vinyl compounds, for example, styrene, a-methyl styrene, vinyl acetate, vinyl propionate, acrylonitrile, vinyl chloride, vinyl fluoride, vinylidene chloride, vinylidene fluoride, butadiene, isopreneydrophilic, and the like, as well as, hydrophilic monomers, for example, hydrophilic olefins and simple /short chain acrylamides, 2 hydroxyethyl acrylate/methacrylate, 2-hydroxypropyl acrylate/methacrylate, 2-dimethylamino - , 2-diethyl amino -, 3-dimethyl aminopropyl - , 3-diethylaminopropyl - , polyethyleglycol mono acrylate or methylate, these can be long chain, MW 2000, acrylamide, methylolacrylamide, methacrylamide, dimethylacrylamide, dimethylmethacrylamide, acrylic acid, methacrylic acid, n-vinylpyrrolidone, 2 and 4 vinyl pyridine, vinyl carbazole, AMPS: 2-acrylamido - 2-methylpropane sulfonic acid, allyl alcohol, propargyl alcohol, hydroxyethylvinyl ether, hydroxybutyl vinyl ether, hydroxycyclohexyl-vinyl ether, and the like. Other suitable co-monomers include cross-linking monomers, for example, ethylene glycol diacrylate/methacrylate, diethylene glycol, triethyleneglycol, vinyl acrylate or methacrylate, allylacrylate or methacrylate, divinyl benzene, trimethylol propane triacrylate or methacrylate, pentaerythritol triacrylate or methacrylate, pentaerythritol diacrylate or methacrylate, glycidyl acrylate or methacrylate, various glycol di-acrylates and methacrylates, 2-chloro ethyl acrylate, and the like, as well as fluorinated monomers, for example, 2-hexafluoropropyl allyl ether, 1,1,2,2, tetrafluoroallyl ether, 2,2,2 trifluoroethyl trifluorovinyl ether, 2,2,2 trifluoroethyl vinyl ether, trifluoromethyl trifluorovinylether, 2,2,2 trifluoroethyl methacrylate, 2,2,3,4,4,4-hexafluorobutylmethacrylate, trimethylol propane, and the like.

By copolymerizing the present compounds with other monomers, oligomers, and polymers, the water-repellency, oil-repellency and stainproofing properties, as well as various characteristics, e.g. cleaning resistance, washing resistance and wear resistance, solubility in solvent, hardness and feeling, and application as a photoresist, can be improved according to necessity. Any suitable relative amounts of the present compounds and other compounds can be used according to the present invention. In certain preferred embodiments, the amount of other polymers used in the present invention is from about 30-90% by weight of the polymer of the present invention. In light of the disclosure herein, those of skill in the art will be readily able to produce polymers of the present invention having physical and chemical properties suitable for a given application, without undue experimentation.

The polymers of the present invention are prepared by polymerizing one or more of the present compounds, optionally in the presence of any additional monomer, oligomer, or polymer compounds to be copolymerized therewith. Any of a wide range of known methods for polymerizing the present compounds can be used according to the present invention. Examples of suitable polymerization methods include bulk polymerization, solution polymerization, emulsion polymerization where the monomers can undergo free radical polymerization, ionic polymerization (cationic and anionic with suitable catalysts), e-beam induced polymerization, UV polymerization addition polymerization such as Diels-Alder coupling and condensation reactions. In certain preferred embodiments, the polymers of the present invention are produced via bulk or solution polymerization. In a particularly preferred embodiment, the present polymers are produced via solution polymerization.

Any of the polymerization methods according to the present invention may comprise reacting one or more compounds of the present invention in the presence of a polymerization initiator and/or a surfactant. Any of a wide range of conventional initiators and surfactants may be used according to the present invention. Suitable surfactants include, anionic surfactants, for example, salts of carboxylic, phosphoric, and sulfonic acids, such as, sodium lauryl sulfate and sodium dioctyl sulfosuccinate, as well as, cationic surfactants, for example, ammonium salts, such as, cetyl trimethylammonium bromide, and, non-ionic surfactants including Tween® polyoxyethylene sorbitan esters, sorbitan esters, and Brij® polyoxyethylene ethers, and the like.

In light of the disclosure herein, those of skill in the art will be readily able to optimize radical initiators, optionally solvents, amounts thereof, and reaction conditions for preparing the present polymers, without undue experimentation. In certain preferred embodiments, the polymerization is conducted at a temperature in the range of about 25° C. to about 100° C., using about 1 mole percent of initiator relative to the amount of compound or compounds of the present invention.

Uses of the Polymers

It has been found that the polymers of the present invention absorb relatively little light even at high frequencies. For example, if the mole ratio of fluorine to hydrogen is no less than about 7:1, it has been observed that the polymers of the present invention have acceptable light transmittance even at a wavelength of 157 nm. Due to cost considerations (i.e., the cost of fluorinated polymers tends to increase as the degree of fluorination increases) and possible process concerns (i.e., highly-fluorinated polymers may be difficult to handle/dissolve), a lower mole ratio of fluorine to hydrogen may be preferred for lower light frequency applications. For example, a fluorine to hydrogen mole ratio of no less than about 7:3 is suitable for polymers used in applications involving 193 nm light. In light of this disclosure, it should be understood that the degree of fluorination can be optimized for a given application and light frequency.

Given the exceptional light transmittance of polymers of the present invention, they find utility in a wide range of applications. Suitable applications include, for example, photoresists, waveguides (e.g., fibers, planar guides in substrates, and optical blocks), adhesives, coatings (IR reflective coatings, anti-reflective coatings, and protective coatings), fiber cladding, photovoltaic cells, and liquid crystal displays.

One application of particular interest is the polymer's use as a photoresist in photolithography. The ability of the polymer of the present invention to maintain high light transmittance at high frequencies renders it particularly suitable for photolithography applications involving light at wavelengths of, for example, 436 nm (g-line), 365 nm (i-line), 193 nm and even 157 nm. Therefore, in a preferred embodiment, the present invention provides for a photolithographic process comprising: (a) applying to a substrate a photoresist comprising a polymer comprising at least one repeating unit derived from a compound of Formula 1, and (b) exposing the substrate and the photoresist to light having a wavelength no greater than about 440 nm. More preferably, the wavelength is no greater than about 200 nm, and even more preferably, the wavelength is no greater than about 160 nm. The photoresist is applied to the substrate using a known solution coating process, for example, spin coating.

Another application of particular interest is the polymer's use as a waveguide. The low light transmittance of the polymers of the present invention render them particular suited for systems operating in the IR region. Preferred operating wavelengths include, for example, 850 nm, 1490-1530 nm (S-band), 1530-1560 nm (C-band), 1560-1605 nm (L-band) signal systems. The waveguide may be fiber, planar, or in the form of a component integrated into an optical package such as a passive device (e.g., add/drop filter, arrayed wave guide grating (AWG), splitters/coupler, and attenuator) or an active device (e.g., optical amplifier, transmitter, receiver and transceiver). Therefore, in a preferred embodiment, the present invention provides for an optical package comprising a component comprising a polymer having at least one repeating unit derived from a compound of Formula 1.

The present invention also provides for a composition comprising at least one polymer according to the present invention. The present compositions may comprise one or more polymers according to the present invention and may further comprise one or more optional other polymeric materials. Examples of suitable other polymeric materials for use in the compositions of the present invention include homopolymers or copolymers of the following: acrylates, such as, methyl methacrylate and ethyl methacrylate, urethanes, butyrals, styrenic copolymers, polyvinylacetates, and the like. In certain embodiments, preferred other polymeric materials comprise copolymers of methyl methacrylate and ethyl methacrylate (available commercially in the form of an extender emulsion). The other polymeric materials of the present invention may be blended, reacted, or cross-linked with the polymers of the present inventions to provide compositions having any of a wide range of desired properties.

In certain embodiments, the compositions of the present invention are emulsions, and preferably, aqueous emulsions. Accordingly, in preferred embodiments, the present compositions comprise water as a solvent. Any suitable amount of water may be used in the present compositions, and in light of the disclosure herein, those of skill in the art will be readily able to select an appropriate amount of water for a given application.

The preferred aqueous compositions of the present invention may further comprise an organic co-solvent. Preferred organic co-solvents are those that tend to be water-miscible and have low toxicity. Examples of preferred other organic solvents include alcohols, ketones, ethers, such as, diethylene glycol diethylether, diethylene glycol dimethylether, propylene glycol dimethylether, water-miscible glycol ether, e.g. propylene glycol monomethylether, propylene glycol mono ethylether, propylene glycolmonopropylether, propylene glycol monobutylether, ethylene glycol monobutylether, dipropylene glycol monomethylether, diethyleneglycol monobutylether; lower esters of monoalkylethers of ethyleneglycol or propylene glycol, such as, propylene glycol monomethyl ether acetate, and mixtures of two or more thereof. Any suitable amount of other organic solvents may be used. Preferably, the amount of organic co-solvent used is less than 10% by weight based on the total weight of the composition.

The compositions of the present invention may also comprise other additives including leveling aids, such as, butyl carbitol, trimethylpentane diol monoisobutyrate, and the like, film-forming polymers and monomers, such as, poly(vinyl alcohol), diethylene glycol methyl ether methacrylate, diethylene glycol 2-ethylhexyl acrylate, poly(ethylene glycol) methyl ether methacrylate, and the like, as well as other additive used conventionally in compositions for the treatment of textile and paper-type substrates.

Any suitable amounts of the present polymers and additives may be used in the compositions of the present invention. In certain embodiments, the compositions comprise from about 0.1 to about 50 percent, by weight of the entire composition, of a polymer according to the present invention. In certain preferred embodiments, from about 2 to about 50 weight percent of polymer of the present invention.

In certain embodiments, the compositions of the present invention are used in methods for treating a substrate comprising applying a composition of the present invention onto a substrate and drying/curing said composition on said substrate.

Any of a wide range of methods for applying the present composition onto a substrate may be used according to the present invention. Suitable methods include, for example, padding, foaming, spraying, spin coating, draw down, dip coating and the like.

In certain preferred embodiments, the composition is dried or cured by exposing the composition to heat. As will be readily appreciated, the composition may be cured using any suitable heat source. While the preferred embodiment involves heat-curing the curable composition, one skilled in the art will appreciate that many variations of the method within the scope of the claims is possible depending on the nature of the curable composition. For example, if desired, the curing of the curable composition may be accelerated using microwave treatment procedures known in the art.

The present invention also provides for a coating or film formed by curing a curable composition of the present invention.

### EXAMPLES

As used in the following examples, the abbreviation “HFP” refers to both the saturated and unsaturated groups derived from hexfluoropropene, i.e., —CF₂CHFCF₃ and —CF═CFCF₃.

### Example 1

This example illustrates the preparation of [2-(1,1,1,2,3,3-hexafluoro-propoxy)-ethoxy]ethene (CF₃CFHCF₂OCH₂CH₂OCH═CH₂).

To a stirred solution of ethylene glycol vinyl ether (400 g, 4.54 mol), acetonitrile (800 mL), and potassium carbonate (314 g, 2.27 mol) was added hexafluoropropene (681 g, 4.54 mol) at a rate to maintain the reaction temperature <45° C. After addition was complete, the reaction mixture was stirred for an additional hour at ambient temperature, then filtered. The filtrate was poured into water (1.5L), stirred for 0.5 hours, then phase separated. The lower organic phase was fractionally distilled. The product fraction boiling at 30° C./3 mm Hg was collected to yield 768 g (71% yield). GC/MS: m/z at 238 for M⁺; ¹⁹F and ¹H spectral data are consistent with the structure.

### Example 2

This example illustrates the preparation of 1,2,3,3,3-pentafluoro-1-(2-vinyloxy-ethoxy) propene (CF₃CF═CFOCH₂CH₂OCH═CH₂).

Under a nitrogen atmosphere, the ethene (238 g, 1 mol) prepared in Example 1 was reacted with potassium-t-butoxide (134.6 g, 1.2 mol) at ambient temperature. The butoxide was added at rate to maintain the reaction temperature <30° C. After the addition was complete, the mixture was stirred for an additional 0.5 h. Vacuum distillation resulted in the isolation of the product. Yield=150.5 g (69%, b.p. 70-75° C./65 mm Hg). The ¹⁹F and ¹H nmr spectral data are consistent with the structure.

### Example 3

This example illustrates the preparation of 1,1,1,2,3,3-Hexafluoro-3-[3-(1,1,2,3,3,3-hexafluoro-propoxy)-propoxy]-propane (CF₃CHFCF₂OCH₂CH₂OCF₂CHFCF₃).

To a stirred solution of ethylene glycol (62.07 g, 1 mol) , acetonitrile (300 mL), and potassium carbonate (25 g, 0.18 mol), was added hexafluoropropene (323.4 g, 2.2 mol) at a rate to maintain the reaction temperature at <45° C. After addition was complete, the reaction mixture was stirred for 0.5 h at ambient temperature, then filtered. The filtrate was added to water (500 mL), stirred for 0.5 h, then phase separated. The lower organic phase was fractionally distilled. The product fraction boiling at 87-93° C. was collected to yield 297.2 g (79% yield). The ¹⁹F and ¹H spectral data are consistent with the proposed structure.

### Example 4

This example illustrates the preparation of 1,2,3,3,3-Pentafluoro-1-(3-pentafluoropropenyloxy-propoxy)-propene (CF₃CF═CFOCH₂CH₂OCF═CFCF₃).

Under a nitrogen atmosphere, the propane prepared in Example 3 was reacted with potassium-t-butoxide (235.7 g, 2.1 mol) at ambient temperature. The butoxide was added at a rate to maintain the reaction temperature <30° C. After the addition was complete, the mixture was stirred for an additional 0.5 h. Vacuum distillation resulted in the isolation of the product. Yield=260 g (82%, b.p. 33-38° C./18 mm Hg). The ¹⁹F and ¹H spectral data is consistent with the structure.

### Example 5

This example illustrates the preparation of 1,2,3,3,3-Pentafluoro-1-[2-(1,1,2,3,3,3-hexafluoro-propoxy)-ethoxy]-propene (CF₃CHFCF₂OCH₂CH₂OCF═CFCF₃).

Under a nitrogen atmosphere, the propane (50 g, 0.13 mol) prepared in example 3 was reacted with potassium-t-butoxide (15.7 g, 0.14 mol) at ambient temperature. The butoxide was added at a rate to maintain the reaction temperature at <30° C. After the addition was complete, the mixture was stirred for an additional 0.5 h. Vacuum distillation resulted in the isolation of the product. Yield=22.2 g 50%, b.p. 45-50° C./50 mm Hg). The ¹⁹F and ¹H spectral data is consistent with the structure.

### Example 6

This example illustrates the preparation of 1-[1,1-Bis(1,1,2,3,3,3-hexafluoropropoxy)butoxy]-1,1,2,3,3,3-hexafluoropropane (CH₃CH₂C(CH₂OCF₂CHFCF₃)₃).

To a stirred solution of trimethylol propane (134.2 g, 1 mol) , acetonitrile (500 mL), and potassium carbonate (25 g. 0.18 mol) was added hexafluoropropene (452.6 g, 3.1 mol) at a rate to maintain the reaction temperature at <45° C. After addition was complete, the reaction mixture was stirred for 0.5 h, then filtered. The filtrate was poured into water (750 mL), stirred for 0.5 h, then phase separated. The lower organic phase was fractionally distilled. The product fraction boiling at 95-102° C./2 mm Hg was collected to yield 426.5 g (73% yield). The ¹⁹F and ¹H nmr spectral data are consistent with the structure.

### Example 7

This example illustrates the preparation of 1-(2,2-Bis-pentafluoropropenyloxymethyl-butoxy)-1,2,3,3-pentafluoro-propene (CH₃CH₂(CH₂OCF═CFCF₃)₃) Under a nitrogen atmosphere, the propane prepared in Example 6 (100 g, 0.17 mol) was reacted with potassium-t-butoxide (57.5 g, 0.51 mol) at ambient temperature. The butoxide was added at a rate to maintain the reaction temperature <30° C. After addition was complete, the mixture was stirred for an additional 0.5 h. Vacuum distillation resulted in the isolation of the product. Yield=58.8 g, (66%, b.p 118-125° C./10 mm Hg). The ¹⁹F and ¹H spectral data are consistent with the structure.

What is claimed is:

1. An optical device comprising a polymer comprising at least one repeating unit derived from a compound of the following formula:
W—Y—O-Z (1)
wherein W is hydrogen, X or X—O—, X is a monovalent unsaturated organic moiety; Y is a divalent organic moiety; and Z a monovalent fluorinated organic moiety.

2. The optical device of claim 1 wherein W is X.

3. The optical device of claim 2 wherein X is selected from the group consisting of substituted or unsubstituted alkenyls, substituted or unsubstituted alkynyls, substituted or unsubstituted aralkyls, substituted or unsubstituted heterocyclic groups, and substituted or unsubstituted vinyl ether groups.

4. The optical device of claim 3 wherein X is selected from the group consisting of substituted or unsubstituted alkenyls and substituted or unsubstituted vinyl ether groups.

5. The optical device of claim 4 wherein X is vinyl, CF₃CF═CF—, CF₂═CF—, CFCl═CF—, or a group derived from ethylvinylether, trimethylolpropane vinyl ether, butylvinyl ether, trimethylol propane divinyl ether, cyclohexylmethyl vinyl ether, pentaerytherital vinylether, glycerolmonovinyl ether, pentaerytherital divinyl ether, glycerol divinyl ether, or pentaerytheriotal trivinyl ether.

6. The optical device of claim 1 wherein W is X—O—.

7. The optical device of claim 4 wherein X is vinyl, CF₃CF═CF—, CF₂═CF—, CFCl═CF—.

8. The optical device of claim 6 wherein X is selected from the group consisting of substituted or unsubstituted alkenyls, substituted or unsubstituted alkynyls, substituted or unsubstituted aralkyls, and substituted or unsubstituted heterocyclic groups.

9. The optical device of claim 7 wherein X is selected from the group consisting of substituted or unsubstituted alkenyls.

10. The optical device of claim 4 wherein X is vinyl, CF₃CF═CF—, CF₂═CF—, or CFCl═CF—.

11. The compound according to claim 1 wherein Y is derived from a monovalent moiety selected from the group consisting of unsubstituted or substituted alkyls, and unsubstituted or substituted aryls.

12. The compound according to claim 11 wherein Y is selected from the group consisting of —CH₂CH₂—, —CH(CH₃)CH₂—, —C(CH₂OZ)₂CH₂—, and —C(CH₃)₂CH₂—.

13. The compound according to claim 11 wherein Y is a moiety of the following formula: —C₆H₄₋ₚ(O-Z)ₚ-, wherein p is from about 0 to about 4.

14. The compound according to claim 13 wherein Y is —C₆H₄-.

15. The compound according to claim 1 wherein each Z is independently selected from the group consisting fluorinated alkyls, fluorinated alkenyls, and fluorinated aryls.

16. The compound according to claim 15 wherein each Z is independently selected from the group consisting of —CHF—CF₃, —CF₂CHF₂, —C(Cl)F—CHF₂, —CF₂—CH(Cl)F, —CF₂CHFCF₃, —CHFCF₂CF₃, —CF₂CF₂CHF₂, —CF(CF₂CF₃)—CH(CF₃)₂, —CF(CF₃)—CH₂—CF(CF₃)₂, —CF(CF₃)—CHF—CF(CF₃)₂, —C(Cl)═CF₂, —C(F)═C(Cl)F, —CF═CF—CF₃, —CF₂—CF═CF₂, —CF═CF—CF₃, and —C(C₂F₅)═C(CF₃)₂.

17. A photoresist comprising a polymer comprising at least one repeating unit derived from a compound of the following formula:
W—Y—O-Z (1)
wherein W is hydrogen, X or X—O—, X is a monovalent unsaturated organic moiety; Y is a divalent organic moiety; and Z a monovalent fluorinated organic moiety.

18. The photoresist of claim 17, wherein the mol ratio of fluorine to hydrogen in said compound is greater than about 7:3.

19. The photoresist of claim 18, wherein the mol ratio of fluorine to hydrogen in said compound is no less than about 7:1.

19. A photolithographic process for manufacturing a chip comprising:
applying to a substrate a photoresist comprising a polymer comprising at least one repeating unit derived from a compound of the following formula:
W—Y—O-Z (1)
wherein W is hydrogen, X or X—O—, X is a monovalent unsaturated organic moiety; Y is a divalent organic moiety; and Z a monovalent fluorinated organic moiety;
exposing said substrate and said photoresist to light having a wavelength no greater than about 440 nm.

20. The photolithographic process of claim 19, wherein said wavelength is no greater than about 200 nm.

21. The photolithographic process of claim 19, wherein said wavelength is no greater than about 160 nm.

22. The photolithographic process of claim 21, wherein the mol ratio of fluorine to hydrogen in said compound is no less than about 7:1.

23. The chip made from the process of claim 19.

24. A waveguide comprising a polymer comprising at least one repeating unit derived from a compound of the following formula:
W—Y—O-Z (1)
wherein W is hydrogen, X or X—O—, X is a monovalent unsaturated organic moiety; Y is a divalent organic moiety; and Z a monovalent fluorinated organic moiety.

25. An optical package comprising a component comprising a polymer having at least one repeating unit derived from a compound of the following formula:
W—Y—O-Z (1)
wherein W is hydrogen, X or X—O—, X is a monovalent unsaturated organic moiety; Y is a divalent organic moiety; and Z a monovalent fluorinated organic moiety.
